(19) United States
(12) Patent Application Publication
(10) Pub. No.: US 2025/0045496 A1
(43) Pub. Date: Feb. 6, 2025

(54) METHOD AND DEVICE FOR GENERATING A VIRTUAL SENSOR SYSTEM

(71) Applicant: Robert Bosch GmbH, Stuttgart (DE)

(72) Inventor: Christoph Zimmer, Stuttgart (DE)

(21) Appl. No.: 18/779,999

(22) Filed: Jul. 22, 2024

(30) Foreign Application Priority Data
Aug. 2, 2023 (DE) 10 2023 207 393.5

(51) Int. Cl. G06F 30/27

(52) U.S. Cl. CPC G06F 30/27

(57) ABSTRACT

A method for automated generation of a system for ascertaining a state variable characterizing a state of a technical system. In the method: a first model is provided, which is configured to ascertain an estimated value of the state variable from the measured variable. Measured pairs of measured variables and in each case assigned state variables are provided. Parameters characterizing the behavior of the first model are adjusted depending on the measured pairs. A machine learning system is provided, which, linked with the first model, produces an overall model configured to ascertain an overall estimated value of the state variable from the measured variable. The machine learning system is trained. An approximation of the machine learning system is ascertained from the machine learning system by means of symbolic regression. The link from the first model and symbolic regression is provided as a generated system.

### FIELD

The present invention relates to a method for automated generation of a system for ascertaining a state variable characterizing a state of a technical system, to a virtual sensor system, to a computer program and to a machine-readable storage medium.

### BACKGROUND INFORMATION

Physical models can be used to model physical interactions for virtual sensors. However, physical models with sufficient accuracy are not available for all applications of virtual sensors. Machine learning methods can close this gap.

German Patent Application No. DE 10 2017 218 922 A1 describes a method for generating virtual sensors by means of autoencoders.

However, virtual sensor systems based on such machine learning systems are relatively new and therefore less tried and tested. Insights into such machine learning systems are also often difficult. This is an obstacle when used in safety-critical applications.

German Patent Application No. DE 10 2020 215 138 A1 describes a method for creating physical equations by means of machine learning methods.

### SUMMARY

The present invention has an advantage that the generated virtual sensor system combines a high modeling quality of the virtual sensor system based on machine learning methods with good interpretability and thus the possibility of validating virtual sensor systems based on physical models.

Further aspects of the present invention are disclosed herein. Advantageous further developments and example embodiment of the present invention are disclosed herein.

In a first aspect, the present invention relates to a method for automated generation of a system for ascertaining a state variable characterizing a state of a technical system depending on a measured variable, i.e. a measured variable characterizing a second state of the technical system (in other words, a method for automated generation of a virtual sensor system). According to an example embodiment of the present invention, the method comprises the following steps:
a first, in particular physical, model is provided, wherein the first model is configured to ascertain an estimated value of the state variable from the measured variable
measured pairs of measured variables and in each case assigned state variables are provided
parameters characterizing the behavior of the first model are or will be adjusted depending on the measured pairs, in particular adjusted in such a way that a deviation between the estimated value ascertained from the measured variable by means of the first model and the state variable is minimized,
a machine learning system is provided, in particular a Gaussian process or a neural network, wherein the machine learning system, linked with the first model, produces an overall model which is configured to ascertain an overall estimated value of the state variable from the measured variable
the machine learning system is or will be trained to minimize an error function which contains a deviation between the state variable and the overall estimated value of the state variable,
an approximation of the machine learning system is ascertained from the machine learning system by means of symbolic regression, in particular in such a way that the approximation of the machine learning system approximates the machine learning system as well as possible,
and wherein the link from the first model and symbolic regression is provided as a generated system.

As a result, the advantages mentioned above may achieved.

In a further development of the present invention, pairs of input data and associated output data of the machine learning system can be generated for symbolic regression by means of the machine learning system and the approximation is ascertained by means of regression of this input data and output data.

In other words, input data is provided and associated output data is provided by means of the machine learning system. Thus, such pairs of input data and associated output data can be easily generated in large numbers, which makes symbolic regression particularly simple.

According to an example embodiment of the present invention, alternatively or additionally, in the symbolic regression, regression candidates and in each case associated fit qualities can be proposed in particular to a user and a selected regression candidate can be received in particular by the user and adopted as an approximation of the machine learning system. This makes it particularly easy to incorporate existing expert knowledge into the generated virtual sensor system. In particular, it is possible that only regression candidates are proposed, of which the associated fit qualities exceed a predeterminable minimum fit quality.

With these methods, the technical system can be an electrical machine, and/or the measured variable can be ascertained by means of a voltage sensor, a temperature sensor or a speed sensor.

Alternatively, according to an example embodiment of the present invention, the technical system can be an energy storage device, in particular a battery or a fuel cell system, and/or the measured variable can be ascertained by means of a voltage sensor or a temperature sensor.

Alternatively, according to an example embodiment of the present invention, the technical system can be a braking and/or steering system of a motor vehicle and/or the measured variable can be ascertained by means of a voltage sensor, a temperature sensor, a speed sensor or a steering angle sensor.

In a further development of the present invention, by means of the generated system in the technical system, the state variable characterizing the state of the technical system can be ascertained depending on measurement data.

In a further aspect, the present invention relates to a virtual sensor system for ascertaining a state variable characterizing a state of a technical system depending on a measured variable characterizing a second state of the technical system, comprising the virtual sensor system generated by the method according to one of the aforementioned methods of the present invention for ascertaining the state variable depending on the measured variable.

In further aspects, the present invention relates to a computer program which is configured to perform any of the aforementioned methods of the present invention as set forth above (i.e., that the computer program includes instructions to cause a computer to perform any of these methods when the computer program is executed by the computer) and a machine-readable storage medium on which the computer program is stored.

In the following, example embodiments of the present invention are explained in more detail with reference to the figures.

### BRIEF DESCRIPTION OF THE DRAWINGS

FIG. 1 schematically shows exemplary embodiments for generating and using the virtual sensor system, according to an example embodiment of the present invention.

FIG. 2 shows an exemplary sequence of the method in a flow chart, according to an example embodiment of the present invention.

### DETAILED DESCRIPTION OF EXAMPLE EMBODIMENTS

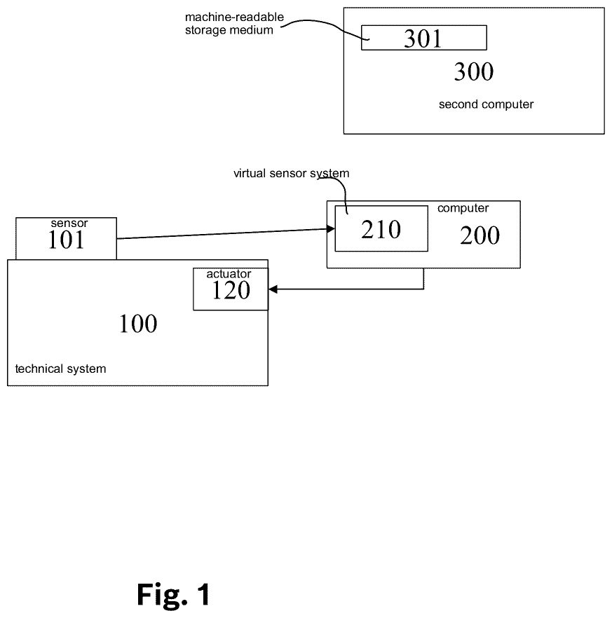

FIG. 1 schematically shows exemplary embodiments for the realization of the present invention. Shown is a technical system (100), in some embodiments a fuel cell system. A sensor (101) is arranged on the technical system (100), in some embodiments a temperature sensor for ascertaining a gas temperature within the fuel cell system. A measured variable measured by the sensor (101) is transmitted to a computer (200) on which a virtual sensor system (210) is implemented and which, by means of a second computer (300), generates, from the measured variable, a further state variable describing the state of the technical system, for example a pressure of a gas in the fuel cell system. The technical system (100) further comprises an actuator (120), for example a valve or a pump, which is actuated depending on the state variable characterizing the state of the technical system (100) ascertained by means of the generated system.

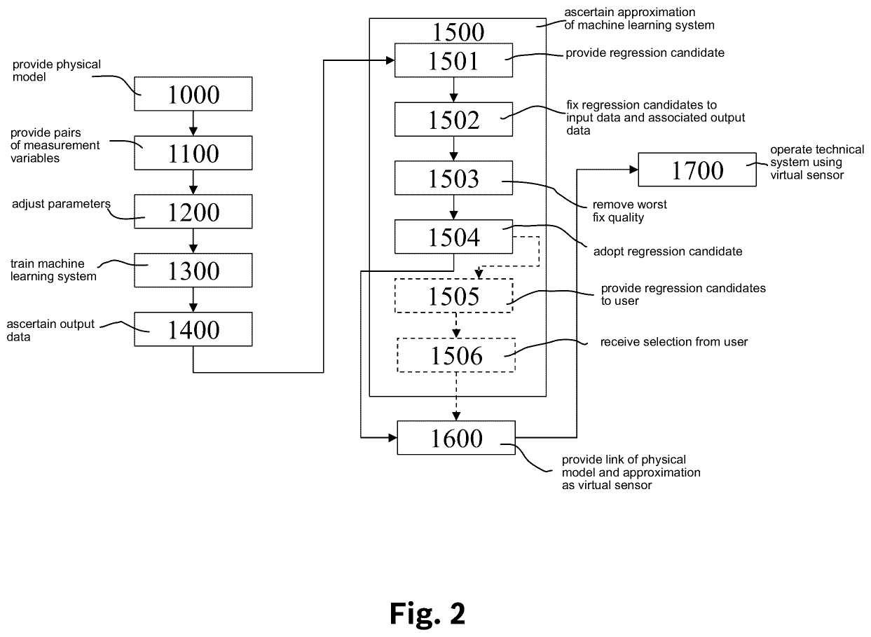

In embodiments, the method for generating the generated system described in FIG. 2 by way of example is realized as a computer program, which is stored on a machine-readable storage medium (301) of the second computer (300).

FIG. 2 illustrates, in a flow chart, a sequence of exemplary embodiments for generating the generated system.

Initially, a physical model is provided (1000), which describes the correlation between the measured variable and the state variable of the technical system to be characterized sufficiently well. In other words, the physical model receives the measured variable at its input and provides a variable at its output that is a good approximation of the state variable of the technical system. In other words, an estimated value of this variable is provided at the output of the physical model.

In some embodiments, this physical system can be parameterized using parameters. Pairs of measured variables ascertained by means of the sensor (101) and associated state variables, which can be measured in the technical system (100) by means of additional sensor technology in a development phase, for example, are then provided (1100). If the physical system can be parameterized by parameters, these parameters are adjusted (1200) in such a way that estimated values of the state variable, which the physical model ascertains depending on the measured variables, correspond as well as possible to the particular associated state variables contained in the pairs.

A machine learning system, in some embodiments a neural network, is then provided, which is linked to the physical model, for example added or multiplied, and the machine learning system is trained (1300) in such a way that the model, linked in this way, ascertains the in each case associated state variable as well as possible from the measured variables. In other words, if the measured variable is provided to the linked model at the input, an overall estimated value of the associated state variable is provided at the output. This training can be done in the usual way, for example, by minimizing a cost function which evaluates a deviation between the overall estimated value of the state variable and the provided state variable.

Now, input data, in embodiments the above measurement data, is fed to the machine learning system and associated particular output data is ascertained at its output (1400).

Based on this input data and output data, an approximation of the machine learning system is ascertained by means of symbolic regression (1500).

In some embodiments, the symbolic regression comprises providing regression candidates from a predeterminable function space, in particular those with a complexity less than a predeterminable maximum complexity (1501).

These regression candidates are fitted to the input data and associated output data (1502), i.e. the particular parameters of the regression candidates are adjusted so that the functional course of the regression candidate matches the pairs as closely as possible. As a measure of how well the course corresponds to these pairs, a particular fit quality is ascertained, which, in embodiments, is greater the better the course corresponds to the pairs (for example, an inverse of the χ² function).

In some embodiments, the regression candidates of which the fit quality is worse than a predeterminable minimum fit quality (1503) are removed.

A regression candidate is now adopted as an approximation of the machine learning system (1504). In some embodiments, this is done by selecting the regression candidate with the best fit. In other, preferred embodiments, the regression candidates are provided to a user together with their particular fit quality (1505) and a selection is received from the user and provided as an approximation (1506).

The link of physical model and approximation is provided as a virtual sensor, i.e. as a system for ascertaining the state variable characterizing a state of the technical system depending on the measured variable (1600).

The technical system (100) as shown in FIG. 1 can then be operated (1700) by means of the virtual sensor (210) obtained in this way.

This ends the method.

1-10. (canceled)

11. A method for automated generation of a system for ascertaining a state variable characterizing a state of a technical system depending on a measured variable characterizing a second state of the technical system, the method comprising the following steps:
providing a first model, wherein the first model is configured to ascertain an estimated value of the state variable from the measured variable;
provide measured pairs of measured variables and in each case assigned state variables;
adjusting parameters characterizing a behavior of the first model depending on the measured pairs;
providing a machine learning system, wherein the machine learning system, linked with the first model, produces an overall model which is configured to ascertain an overall estimated value of the state variable from the measured variable;
training the machine learning system to minimize an error function which contains a deviation between the state variable and the overall estimated value of the state variable;
ascertaining an approximation of the machine learning system from the machine learning system using symbolic regression; and
providing the link from the first model and symbolic regression is provided as a generated system.

12. The method according to claim 11, wherein pairs of input data and associated output data of the machine learning system are generated for the symbolic regression using the machine learning system and the approximation using regression of the input data and the output data.

13. The method according to claim 11, wherein, in the symbolic regression, regression candidates and in each case associated fit qualities are proposed and a selected regression candidate is received by a user and is adopted as the approximation of the machine learning system.

14. The method according to claim 11, wherein the technical system is an electric machine and/or the measured variable is ascertained using a voltage sensor or a temperature sensor or a speed sensor.

15. The method according to claim 11, wherein: (i) the technical system is an energy storage device including a battery or a fuel cell system, and/or (ii) the measured variable is ascertained using a voltage sensor or a temperature sensor.

16. The method according to claim 11, wherein: (i) the technical system is a braking and/or steering system of a motor vehicle, and/or (ii) the measured variable is ascertained using a voltage sensor or a temperature sensor or a speed sensor or a steering angle sensor.

17. The method according to claim 11, wherein the state variable characterizing the state of the technical system is ascertained using the generated system in the technical system depending on measurement data.

18. A virtual sensor system for ascertaining a state variable characterizing a state of a technical system depending on a measured variable characterizing a second state of the technical system, the virtual sensor system being generated by:
providing a first model, wherein the first model is configured to ascertain an estimated value of the state variable from the measured variable;
provide measured pairs of measured variables and in each case assigned state variables;
adjusting parameters characterizing a behavior of the first model depending on the measured pairs;
providing a machine learning system, wherein the machine learning system, linked with the first model, produces an overall model which is configured to ascertain an overall estimated value of the state variable from the measured variable;
training the machine learning system to minimize an error function which contains a deviation between the state variable and the overall estimated value of the state variable;
ascertaining an approximation of the machine learning system from the machine learning system using symbolic regression; and
providing the link from the first model and symbolic regression is provided as a generated system.

19. A non-transitory machine-readable storage medium on which is stored a computer program for automated generation of a system for ascertaining a state variable characterizing a state of a technical system depending on a measured variable characterizing a second state of the technical system, the computer program, when executed by a computer, causing the computer to perform the following steps:
providing a first model is provided, wherein the first model is configured to ascertain an estimated value of the state variable from the measured variable;
provide measured pairs of measured variables and in each case assigned state variables;
adjusting parameters characterizing a behavior of the first model depending on the measured pairs;
providing a machine learning system, wherein the machine learning system, linked with the first model, produces an overall model which is configured to ascertain an overall estimated value of the state variable from the measured variable;
training the machine learning system to minimize an error function which contains a deviation between the state variable and the overall estimated value of the state variable;
ascertaining an approximation of the machine learning system from the machine learning system using symbolic regression; and
providing the link from the first model and symbolic regression is provided as a generated system.
